(19) United States
(12) Patent Application Publication
(10) Pub. No.: US 2010/0013559 A1
(43) Pub. Date: Jan. 21, 2010

(54) High frequency amplifying device

(76) Inventors: Lee B. Max, Tucson, AR (US); Robert S. McDonald, Reno, NV (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/012,306

(22) Filed: Feb. 1, 2008

Related U.S. Application Data
(60) Provisional application No. 60/899,084, filed on Feb. 2, 2007.

(51) Int. Cl. H03F 3/16

(52) U.S. Cl. 330/277

(57) ABSTRACT

An amplifying device includes a base plate and an integrated circuit (IC) package mounted on the base plate. The IC package includes a radio frequency (RF) output terminal and a power switching metal-oxide-semiconductor field-effect transistor (MOSFET) die mounted on the RF output terminal. The amplifying device also includes impedance matching circuitry coupled to the power switching MOSFET and the RF output terminal and an insulator substrate mounted on the base plate having thermal conductivity to provide electrical isolation and thermal transfer from the RF output terminal.

This is a non-provisional application based on provisional application Ser. No. 60/899,084 filed on Feb. 2, 2007, and claims priority thereof.

### FIELD OF THE INVENTION

The present invention relates to high frequency amplifiers; more particularly, the present invention relates to the use of low cost, high power, packaged transistors in high frequency power amplification applications.

### BACKGROUND

High frequency power amplifier stages typically include transistors and impedance matching circuitry. However, high power amplifiers that operate at frequencies of 100 MHz and above currently use expensively packaged, high frequency, power transistors. High power, packaged transistors that operate above 100 MHz are expensive (e.g., $75-$125 US). This results in the cost of producing high power, high frequency amplifiers, extremely high.

It would be desirable to be able to use low cost, packaged transistors in power amplifying devices to reduce overall production costs. However conventional mechanical/electrical amplifier design techniques prevent low cost, packaged transistors from being used. To properly use a low cost, high power, packaged transistor at high frequencies, the connection path between the high voltage output terminal and the grounded heatsink, must 1) have a very low thermal resistance, 2) be electrically insulating, and 3) have a low electrical capacitance. Conventional mechanical/electrical mounting techniques fail to meet this combined requirement. That design limitation reduces the high frequency capability of the low cost, high power, packaged transistors.

### BRIEF DESCRIPTION OF THE DRAWINGS

The invention is illustrated by way of example and not limitation in the figures of the accompanying drawings, in which like references indicate similar elements, and in which:

FIG. 1 is illustrates one embodiment of a side view of a low cost, packaged transistor;

FIG. 2 illustrates one embodiment of a top view of two (2) packaged transistors held down with a single mounting bar; and

FIG. 3 illustrates one embodiment of a side view of an assembled amplifying circuit.

### DETAILED DESCRIPTION

A high power amplifying device is described. Particularly, the amplifying device implements a thermal/electrical mounting technique for high power transistors that significantly extends the upper frequency of high power operation. In the following detailed description of the present invention numerous specific details are set forth in order to provide a thorough understanding of the present invention. However, it will be apparent to one skilled in the art that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

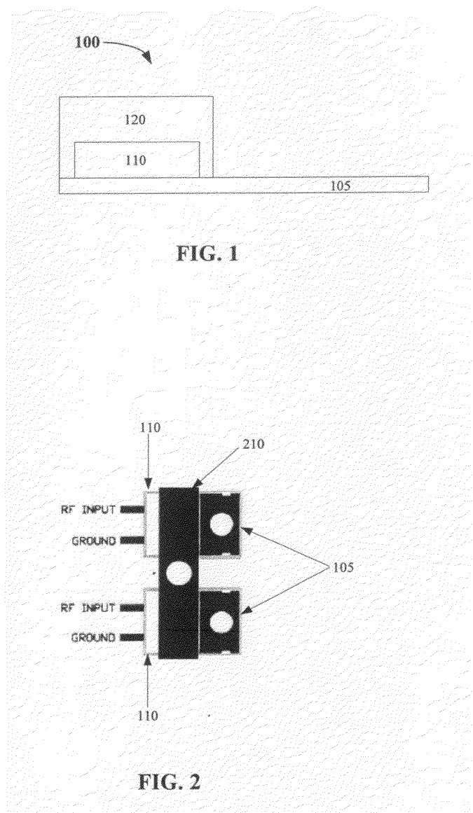

FIG. 1 illustrates one embodiment of a side view of a transistor package 100. Package 100 includes a transistor die 110 mounted on a RF output terminal 105. In one embodiment, transistor die 110 is a power switching metal-oxide-semiconductor field-effect transistor (MOSFET) die that is implemented is a high frequency power transistor. However in other embodiments, other transistor die and packages may be implemented.

According to one embodiment, RF output terminal 105 is a high voltage RF output terminal that receives an output signal that has been amplified by transistor die 110. Also mounted on output terminal 105 is a cover 120 that is used as a protective cover for die 110.

FIG. 2 illustrates one embodiment of a top view of two transistor packages 100 held down via a clamping bar 210. From the top view, RF input and ground leads are visible at the input to each transistor package 100. Further, screw holes are included at each output terminal 105 to enable screws to be inserted to secure the packages 100.

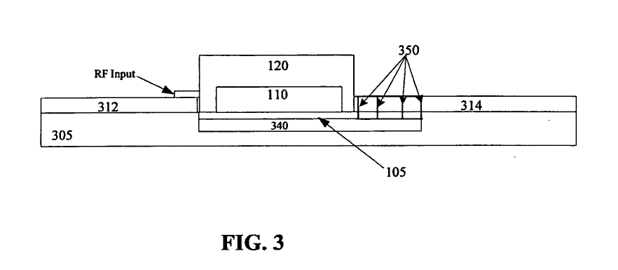

FIG. 3 illustrates one embodiment of a side view of an amplifying device incorporating package 100. The amplifying device includes a metal base plate 305, which operates as a thermal pad to enable heat generated by package 100 to be dissipated. Mounted on top of metal base plate 305 are input printed circuit board (PCB) 312 and output PCB 314. PCBs 312 and 314 are used to mechanically support electronic circuit components and to electrically connect those components to packaged transistor 100 via conductive traces. In one embodiment, the circuit components comprise impedance matching circuitry that is implemented to extract maximum high frequency performance from the packaged transistor 100.

Also mounted on base plate 305 is an insulator 340, upon which sits RF output terminal 105. According to one embodiment, insulator 340 is an insulator with very high thermal conductivity. In such an embodiment, insulator 340 is comprised of a thick (e.g., 0.090 in.) aluminum nitride substrate that provides efficient thermal transfer from RF output terminal 105.

In conventional amplifying devices a thin Mylar insulator is placed between the RF output terminal and a heat sink. Such a configuration provides electrical isolation, but operates as an inefficient thermal conductor. Therefore, in conventional amplifying devices the insulator is kept very thin (e.g., 0.005 in.) to enable heat transfer between the RF output terminal and a heat sink. However, such a thin insulator creates a relatively high electrical capacitance between the RF output terminal and the metal base plate. This high electrical capacitance drastically reduces high frequency performance.

The high thermal conductivity aluminum nitride layer described in the present embodiment has a very high thermal conductivity, which enables the insulator 340 to be considerably thicker. Accordingly, the thick insulator 340 reduces the capacitance between the high voltage RF output terminal and the grounded metal base plate, thereby increasing the high frequency performance.

In other embodiments, the aluminum nitride insulator 340 may be replaced with other materials having similar electrical/insulation properties without departing from the scope of the invention.

Referring back to FIG. 3, PCB 314 includes through holes 350 that enable bottom and top copper layers of PCB 314 to be electrically coupled. The bottom copper layers of PCB 314 are mechanically and electrically in direct contact with the high voltage RF output terminal 105. The through holes 350 allow RF output signal from terminal 105 to have a high frequency, low loss connection to the top layer of PCB 314. The result is a high power output circuit that functions efficiently at high frequencies. In a further embodiment, the bottom copper layer of PCB 314 is mechanically pressed to RF output terminal 105.

The above-described amplifying device configuration enables relatively inexpensive transistors designed for medium frequency operation (e.g., <1 MHz) to be operated at very high frequencies (e.g., 100 MHz). By replacing expensive RF power transistors with inexpensive power switching MOSFETs, lower dollars per watt costs are incurred for high power, high frequency amplifier circuits.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as essential to the invention.

What is claimed is:

1. An amplifying device comprising:
a base plate;
an integrated circuit (IC) package mounted on the base plate including:
a radio frequency (RF) output terminal; and
a power switching metal-oxide-semiconductor field-effect transistor (MOSFET) die mounted on the RF output terminal;
impedance matching circuitry coupled to the power switching MOSFET and the RF output terminal; and
an insulator substrate mounted on the base plate having thermal conductivity to provide electrical isolation and thermal transfer from the RF output terminal.

2. The device of claim 1 wherein the impedance matching circuitry comprises:
an input printed circuit board (PCB) having input electronic components coupled to the power switching MOSFET die; and
an output PCB having output electronic components coupled to the RF output terminal.

3. The device of claim 2 wherein the output PCB comprises holes to enable a low loss connection between the output electronic components on a top layer of the output PCB and the RF output terminal.

4. The device of claim 3 wherein a high frequency RF signal is transmitted from the RF output terminal to the output electronic components.

5. The device of claim 2 wherein a bottom layer of the output PCB is mechanically pressed to the RF output terminal.

6. The device of claim 1 wherein the base plate is a thermal pad that dissipates thermal energy from the RF output terminal.

7. The device of claim 1 wherein the insulator substrate is comprised of a thickness to reduce a capacitance between the RF output terminal and the base plate.

8. The device of claim 7 wherein the insulator substrate is comprised of aluminum nitride.

9. The device of claim 1 further comprising a second IC package mounted on the base plate.

10. The device of claim 9 further comprising a clamp bar to support the IC package and the second IC package.

11. The device of claim 9 further comprising ground leads coupled to the IC package and the second IC package.
